(19) United States
(12) Patent Application Publication
(10) Pub. No.: US 2025/0323026 A1
(43) Pub. Date: Oct. 16, 2025

(54) SUPPORT MEMBER, SUBSTRATE SUPPORT, AND PLASMA PROCESSING APPARATUS

(71) Applicant: Tokyo Electron Limited, Tokyo (JP)

(72) Inventor: Shinya ISHIKAWA, Miyagi (JP)

(73) Assignee: Tokyo Electron Limited, Tokyo (JP)

(21) Appl. No.: 19/250,479

(22) Filed: Jun. 26, 2025

Related U.S. Application Data
(63) Continuation of application No. PCT/JP2023/047062, filed on Dec. 27, 2023.

(30) Foreign Application Priority Data
Jan. 10, 2023 (JP) 2023-001904

(51) Int. Cl. H01J 37/32

(52) U.S. Cl. CPC H01J 37/32715; H01J 2237/2007

(57) ABSTRACT

A support member supports a substrate. The support member includes a dielectric portion, a first layer, and a second layer. The dielectric portion has a substrate support surface. The first layer is in the dielectric portion and includes at least one first heater. The second layer is in the dielectric portion and includes at least one second heater. The at least one second heater has a resistance different from a resistance of the at least one first heater.

### CROSS-REFERENCE TO RELATED APPLICATIONS

This application is a continuation application of International Application PCT/JP2023/047062, filed on Dec. 27, 2023, and designating the U.S., which claims priority to Japanese Patent Application No. 2023-001904, filed on Jan. 10, 2023, the entire contents of each of which are incorporated herein by reference.

### FIELD

Embodiments of the disclosure relate to a support member, a substrate support, and a plasma processing apparatus.

### BACKGROUND

A plasma processing apparatus is used to perform plasma processing on substrates. A plasma processing apparatus described in Patent Literature 1 includes a support member, a base, and wires. The support member includes a body, a heater, and contacts. The body includes a mount area for receiving a substrate and a peripheral area surrounding the mount area. The heater controls the temperature of the substrate. The contacts are electrically coupled to the heater and a power supply with the wires. The base has through-holes for the wires. The through-holes are in the peripheral area of the base.

### CITATION LIST

### Patent Literature

Patent Literature 1: Japanese Unexamined Patent Application Publication No. 2016-1688.

### BRIEF SUMMARY

### Technical Problem

One or more aspects of the disclosure are directed to a technique for controlling the temperature of a substrate over a wide temperature range.

### Solution to Problem

A support member according to one exemplary embodiment supports a substrate. The support member includes a dielectric portion, a first layer, and a second layer. The dielectric portion has a substrate support surface. The first layer is in the dielectric portion and includes at least one first heater. The second layer is in the dielectric portion and includes at least one second heater. The at least one second heater has a resistance different from a resistance of the at least one first heater.

### Advantageous Effects

The technique according to the above aspect of the disclosure allows control of the temperature of a substrate over a wide temperature range.

### BRIEF DESCRIPTION OF DRAWINGS

FIG. 1 is a diagram of a plasma processing system with an example structure.

FIG. 2 is a diagram of a capacitively coupled plasma processing apparatus with an example structure.

FIG. 3 is a diagram of a substrate support according to one exemplary embodiment.

FIG. 4 is a schematic diagram describing wiring in the substrate support according to the exemplary embodiment.

FIG. 5 is a partial cross-sectional view of terminals in the substrate support with an example structure according to the exemplary embodiment.

### DETAILED DESCRIPTION

Exemplary embodiments will now be described in detail with reference to the drawings. In the figures, like reference numerals denote like or corresponding components.

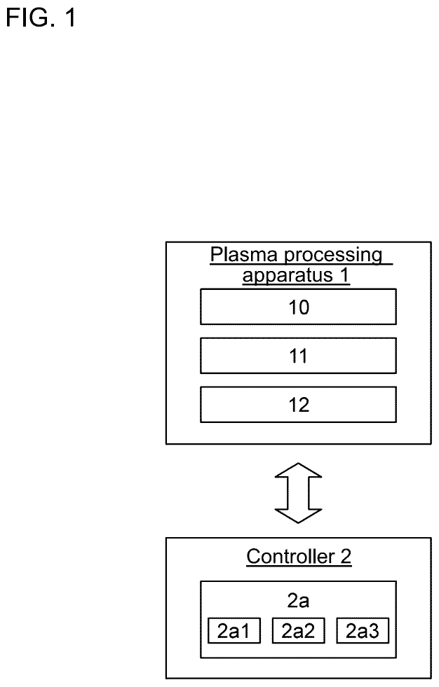

FIG. 1 is a diagram of a plasma processing system with an example structure. In one embodiment, the plasma processing system includes a plasma processing apparatus 1 and a controller 2. The plasma processing system is an example of a substrate processing system. The plasma processing apparatus 1 is an example of a substrate processing apparatus. The plasma processing apparatus 1 includes a plasma processing chamber 10, a substrate support 11, and a plasma generator 12. The plasma processing chamber 10 has a plasma processing space. The plasma processing chamber 10 has at least one gas inlet for supplying at least one process gas into the plasma processing space and at least one gas outlet for discharging the gas from the plasma processing space. The gas inlet is connected to a gas supply 20 (described later). The gas outlet is connected to an exhaust system 40 (described later). The substrate support 11 is located in the plasma processing space and has a substrate support surface for supporting a substrate. The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium such as a CD-ROM or DVD, and/or the memory of a FPGA or ASIC.

The plasma generator 12 generates plasma from at least one process gas supplied into the plasma processing space. The plasma generated in the plasma processing space may be, for example, capacitively coupled plasma (CCP), inductively coupled plasma (ICP), electron cyclotron resonance (ECR) plasma, helicon wave plasma (HWP), or surface wave plasma (SWP). Various plasma generators including an alternating current (AC) plasma generator and a direct current (DC) plasma generator may be used. In one embodiment, an AC signal (AC power) used in the AC plasma generator has a frequency in a range of 100 kHz to 10 GHz. Thus, the AC signal includes a radio-frequency (RF) signal and a microwave signal. In one embodiment, the RF signal has a frequency in a range of 100 kHz to 150 MHz.

The controller 2 processes computer-executable instructions that cause the plasma processing apparatus 1 to perform various steps described in one or more embodiments of the disclosure. The controller 2 may control the components of the plasma processing apparatus 1 to perform the various steps described herein. In one embodiment, some or all of the components of the controller 2 may be included in the plasma processing apparatus 1. The controller 2 may include a processor 2a1, a storage 2a2, and a communication interface 2a3. The controller 2 is implemented by, for example, a computer 2a. The processor 2al may perform various control operations by loading a program from the storage 2a2 and executing the loaded program. The program may be prestored in the storage 2a2 or may be obtained through a medium as appropriate. The obtained program is stored into the storage 2a2 to be loaded from the storage 2a2 and executed by the processor 2a1. The medium may be one of various storage media readable by the computer 2a, or a communication line connected to the communication interface 2a3. The processor 2al may be a central processing unit (CPU). The storage 2a2 may include a random-access memory (RAM), a read-only memory (ROM), a hard disk drive (HDD), a solid-state drive (SSD), or a combination of these. The communication interface 2a3 may communicate with the plasma processing apparatus 1 through a communication line such as a local area network (LAN).

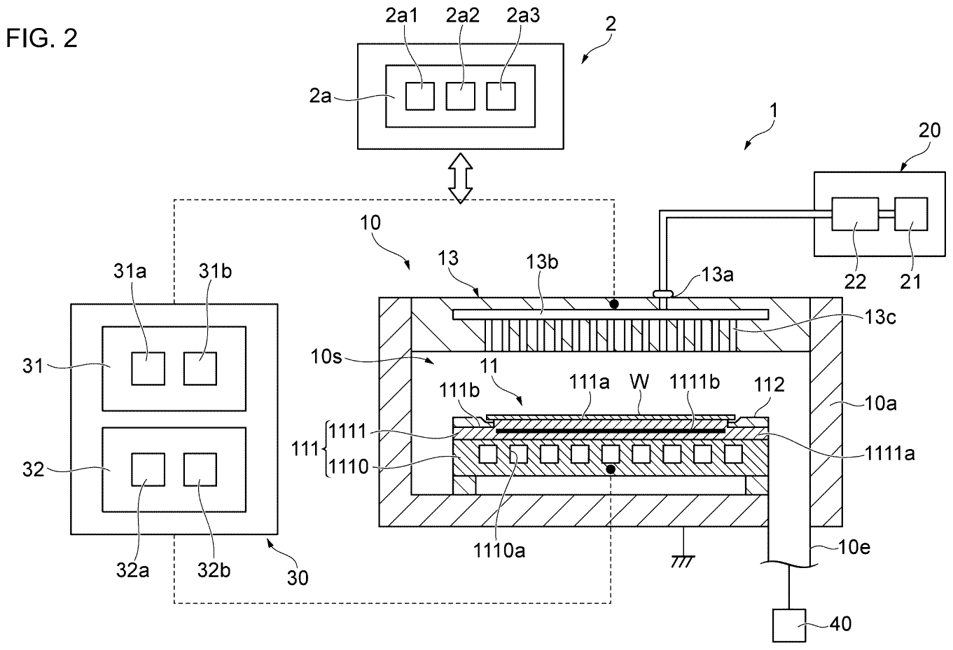

A capacitively coupled plasma processing apparatus with an example structure will now be described as an example of the plasma processing apparatus 1. FIG. 2 is a diagram of the capacitively coupled plasma processing apparatus with the example structure.

The capacitively coupled plasma processing apparatus 1 includes the plasma processing chamber 10, the gas supply 20, a power supply 30, and the exhaust system 40. The plasma processing apparatus 1 also includes the substrate support 11 and a gas inlet unit. The gas inlet unit allows at least one process gas to be introduced into the plasma processing chamber 10. The gas inlet unit includes a shower head 13. The substrate support 11 is located in the plasma processing chamber 10. The shower head 13 is located above the substrate support 11. In one embodiment, the shower head 13 defines at least a part of the ceiling of the plasma processing chamber 10. The plasma processing chamber 10 has a plasma processing space 10s defined by the shower head 13, a side wall 10a of the plasma processing chamber 10, and the substrate support 11. The plasma processing chamber 10 is grounded. The shower head 13 and the substrate support 11 are electrically insulated from the housing of the plasma processing chamber 10.

The substrate support 11 includes a body 111 and a ring assembly 112. The body 111 includes a central area 111a for supporting a substrate W and an annular area 111b for supporting the ring assembly 112. The substrate W is, for example, a wafer. The annular area 111b of the body 111 surrounds the central area 111a of the body 111 as viewed in plan. The substrate W is placed on the central area 111a of the body 111. The ring assembly 112 is placed on the annular area 111b of the body 111 to surround the substrate W on the central area 111a of the body 111. Thus, the central area 111a is also referred to as a substrate support surface for supporting the substrate W. The annular area 111b is also referred to as a ring support surface for supporting the ring assembly 112.

In one embodiment, the body 111 includes a base 1110 and an electrostatic chuck (ESC) 1111. The base 1110 includes a conductive member. The conductive member in the base 1110 may serve as a lower electrode. The ESC 1111 is located on the base 1110. The ESC 1111 includes a ceramic member 1111a and an electrostatic electrode 1111b inside the ceramic member 1111a. The ceramic member 1111a has the central area 111a. In one embodiment, the ceramic member 1111a also includes the annular area 111b. The annular area 111b may be included in a separate member surrounding the ESC 1111, such as an annular ESC or an annular insulating member. In this case, the ring assembly 112 may be placed on either the annular ESC or the annular insulating member or may be placed on both the ESC 1111 and the annular insulating member. At least one RF/DC electrode coupled to an RF power supply 31, a DC power supply 32, or both (described later) may be located inside the ceramic member 1111a. In this case, at least one RF/DC electrode serves as a lower electrode. When a bias RF signal, a DC signal, or both (described later) are provided to at least one RF/DC electrode, the RF/DC electrode is also referred to as a bias electrode. The conductive member in the base 1110 and at least one RF/DC electrode may serve as multiple lower electrodes. The electrostatic electrode 1111b may also serve as a lower electrode. Thus, the substrate support 11 includes at least one lower electrode.

The ring assembly 112 includes one or more annular members. In one embodiment, one or more annular members include one or more edge rings and at least one cover ring. The edge rings are formed from a conductive material or an insulating material. The cover ring is formed from an insulating material.

The substrate support 11 may also include a temperature control module that adjusts the temperature of at least one of the ESC 1111, the ring assembly 112, or the substrate to a target temperature. The temperature control module may include a heater, a heat transfer medium, a channel 1110a, or a combination of these. The channel 1110a allows a heat transfer fluid such as brine or gas to flow. In one embodiment, the channel 1110a is defined in the base 1110, and one or more heaters are located inside the ceramic member 1111a in the ESC 1111. The substrate support 11 may include a heat transfer gas supply to supply a heat transfer gas into a space between the back surface of the substrate W and the central area 111a.

The shower head 13 introduces at least one process gas from the gas supply 20 into the plasma processing space 10s. The shower head 13 includes at least one gas inlet 13a, at least one gas-diffusion compartment 13b, and multiple gas guides 13c. The process gas supplied to the gas inlet 13a passes through the gas-diffusion compartment 13b and is introduced into the plasma processing space 10s through the multiple gas guides 13c. The shower head 13 also includes at least one upper electrode. In addition to the shower head 13, the gas inlet unit may include one or more side gas injectors (SGIs) installed in one or more openings in the side wall 10a.

The gas supply 20 may include at least one gas source 21 and at least one flow controller 22. In one embodiment, the gas supply 20 allows supply of at least one process gas from the corresponding gas source 21 to the shower head 13 through the corresponding flow controller 22. The flow controller 22 may include, for example, a mass flow controller or a pressure-based flow controller. The gas supply 20 may further include at least one flow rate modulator that allows supply of at least one process gas at a modulated flow rate or in a pulsed manner.

The power supply 30 includes the RF power supply 31 that is coupled to the plasma processing chamber 10 through at least one impedance matching circuit. The RF power supply 31 provides at least one RF signal (RF power) to at least one lower electrode, to at least one upper electrode, or to both the electrodes. This causes plasma to be generated from at least one process gas supplied into the plasma processing space 10s. The RF power supply 31 may thus at least partially serve as the plasma generator 12. A bias RF signal is provided to at least one lower electrode to generate a bias potential in the substrate W, thus drawing ion components in the plasma to the substrate W.

In one embodiment, the RF power supply 31 includes a first RF generator 31a and a second RF generator 31b. The first RF generator 31a is coupled to at least one lower electrode, to at least one upper electrode, or to both the electrodes through at least one impedance matching circuit and generates a source RF signal (source RF power) for plasma generation. In one embodiment, the source RF signal has a frequency in a range of 10 to 150 MHz. In one embodiment, the first RF generator 31a may generate multiple source RF signals with different frequencies. The generated one or more source RF signals are provided to at least one lower electrode, to at least one upper electrode, or to both the electrodes.

The second RF generator 31b is coupled to at least one lower electrode through at least one impedance matching circuit and generates a bias RF signal (bias RF power). The frequency of the bias RF signal may be the same as or different from the frequency of the source RF signal. In one embodiment, the bias RF signal has a lower frequency than the source RF signal. In one embodiment, the bias RF signal has a frequency in a range of 100 kHz to 60 MHz. In one embodiment, the second RF generator 31b may generate multiple bias RF signals with different frequencies. The generated one or more bias RF signals are provided to at least one lower electrode. In various embodiments, at least one of the source RF signal or the bias RF signal may be pulsed.

The power supply 30 may include the DC power supply 32 coupled to the plasma processing chamber 10. The DC power supply 32 includes a first DC generator 32a and a second DC generator 32b. In one embodiment, the first DC generator 32a is coupled to at least one lower electrode and generates a first DC signal. The generated first DC signal is applied to at least one lower electrode. In one embodiment, the second DC generator 32b is coupled to at least one upper electrode and generates a second DC signal. The generated second DC signal is applied to at least one upper electrode.

In various embodiments, the first DC signal and the second DC signal may be pulsed. In this case, a sequence of voltage pulses is applied to at least one lower electrode, to at least one upper electrode, or to both the electrodes. The voltage pulses may have a rectangular, trapezoidal, or triangular pulse waveform, or a combination of these pulse waveforms. In one embodiment, a waveform generator for generating a sequence of voltage pulses based on DC signals is coupled between the first DC generator 32a and at least one lower electrode. Thus, the first DC generator 32a and the waveform generator form a voltage pulse generator. When the second DC generator 32b and the waveform generator form a voltage pulse generator, the voltage pulse generator is coupled to at least one upper electrode. The voltage pulses may have positive polarity or negative polarity. The sequence of voltage pulses may include one or more positive voltage pulses and one or more negative voltage pulses within one cycle. The power supply 30 may include the first DC generator 32a and the second DC generator 32b in addition to the RF power supply 31, or the first DC generator 32a may replace the second RF generator 31b.

The exhaust system 40 is connectable to, for example, a gas outlet 10e in the bottom of the plasma processing chamber 10. The exhaust system 40 may include a pressure control valve and a vacuum pump. The pressure control valve regulates the pressure in the plasma processing space 10s. The vacuum pump may include a turbomolecular pump, a dry pump, or a combination of these.

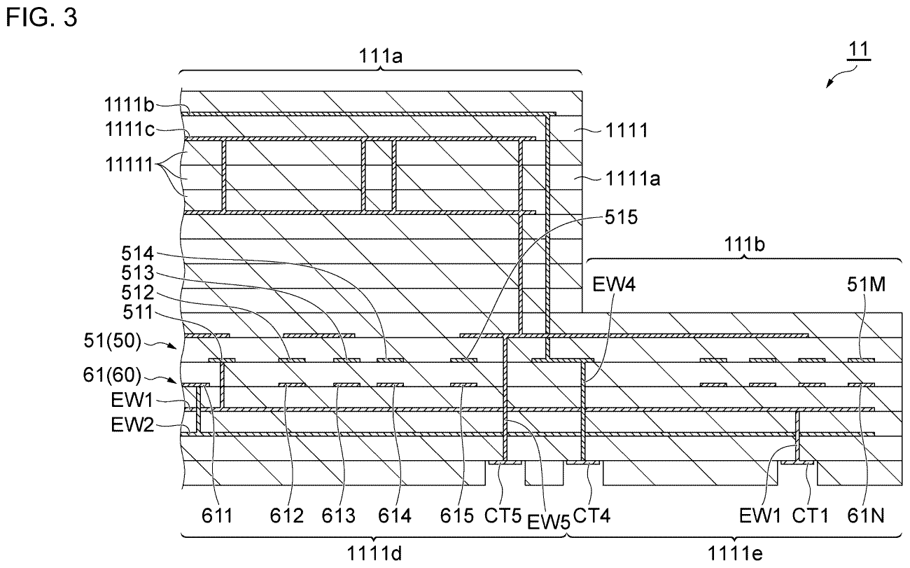

A plasma processing apparatus according to one exemplary embodiment will now be described with reference to FIG. 3. FIG. 3 is a diagram of a support member and a substrate support according to the exemplary embodiment. The substrate support 11 shown in FIG. 3 is an example of a substrate support. The ESC 1111 is an example of a support member. The ceramic member 1111a is an example of a dielectric portion. The ceramic member 1111a includes multiple layers 11111 formed from ceramic. The multiple layers 11111 are stacked on one another in, for example, the vertical direction. The central area 111a is an example of a substrate support surface.

As shown in FIG. 3, the ESC 1111 includes a first area 1111d and a second area 1111e. The first area 1111d is disk-shaped. The first area 1111d includes the central area 111a in its upper portion. The second area 1111e is cylindrical and surrounds the outer peripheral surface of the first area 1111d. The second area 1111e includes the annular area 111b in its upper portion. The ESC 1111 includes a lower electrode 1111c inside the ceramic member 1111a. The lower electrode 1111c is coupled to at least one of the first RF generator 31a, the second RF generator 31b, or the first DC generator 32a. At least one of the source RF signal, the bias RF signal, or the first DC signal is provided to the lower electrode 1111c.

The ESC 1111 includes a first layer 50 and a second layer 60. The first layer 50 and the second layer 60 are located inside the ceramic member 1111a in the ESC 1111. The first layer 50 is located, for example, above the second layer 60. The first layer 50 and the second layer 60 may be at any positions relative to each other in the vertical direction. For example, some of the multiple layers 11111 of ceramic are located between the first layer 50 and the second layer 60.

The first layer 50 includes at least one first heater 51. The first layer 50 includes multiple first heaters 51. In the illustrated example, the first layer 50 includes M first heaters 51, or first heaters 511 to 51M. The multiple first heaters 51 are arranged between the central area 111a and the lower surface of the ESC 1111 and between the annular area 111b and the lower surface of the ESC 1111. The first heaters 51 are arranged in a horizontal plane parallel to the central area 111a and the annular area 111b. The first heaters 51 are arranged in the same plane in the first layer 50 and do not overlap each other in the plane. The first heaters 51 in the first layer 50 are distributed to heat the entire substrate uniformly.

The second layer 60 includes at least one second heater 61. In the illustrated example, the second layer 60 includes N second heaters 61, or second heaters 611 to 61N. For example, the number M of the first heaters 51 is the same as the number N of the second heaters 61. The multiple second heaters 61 are arranged between the central area 111a and the lower surface of the ESC 1111 and between the annular area 111b and the lower surface of the ESC 1111. The second heaters 61 are arranged in a horizontal plane parallel to the central area 111a and the annular area 111b. The second heaters 61 are arranged in the same plane in the second layer 60 and do not overlap each other in the plane. The second heaters 61 in the second layer 60 are distributed to heat the entire substrate uniformly. The first layer 50 includes multiple zones including the second heaters 61, and the second layer 60 includes multiple zones including the second heaters 61. The zones in the first layer 50 and the zones in the second layer 60 may have the same or similar shape, size, and layout.

The second heaters 61 have a resistance different from the resistance of the first heaters 51. The first heaters 51 and the second heaters 61 have different temperature ranges for heating. The first heaters 51 in the first layer 50 include, for example, heating resistors with the same resistance. The second heaters 61 in the second layer 60 include, for example, heating resistors with the same resistance. The heating resistors in the first heaters 51 and the second heaters 61 are formed from, for example, metal.

In one embodiment, each first heater 51 is thicker and shorter than each second heater 61. The first heaters 51 have a high resistance in a relatively high-temperature range within which the first heaters 51 are used. The voltage applied to the first heaters 51 in the high-temperature range can be adjusted to precisely adjust the current flowing through the first heaters 51. Thus, the first heaters 51 can perform precise temperature adjustment in a relatively high-temperature range (a first temperature range described later). In contrast, each second heater 61 is thinner and longer than each first heater 51. The second heaters 61 have a high resistance in a relatively low-temperature range within which the second heaters 61 are used. The voltage applied to the second heaters 61 can be adjusted to precisely adjust the current flowing through the second heaters 61. Thus, the second heaters 61 can perform precise temperature adjustment in a relatively low-temperature range (a second temperature range described later). As described above, the first heaters 51 are suitable for heating the substrate to a high temperature. The second heaters 61 are suitable for heating the substrate to a relatively low temperature. The ESC 1111 can thus control the temperature of the substrate over a wide temperature range.

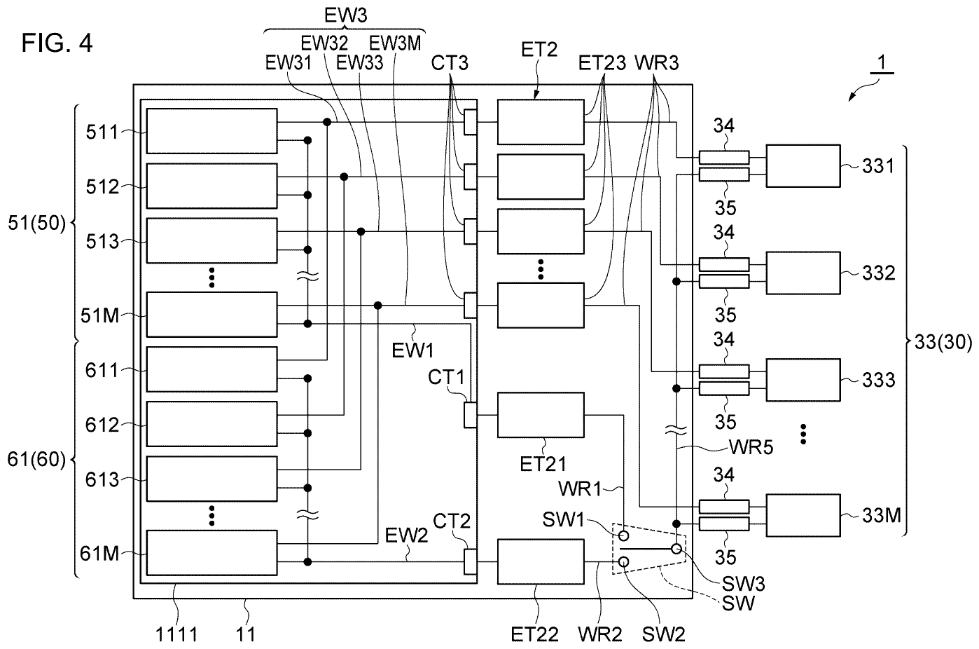

FIG. 4 is a schematic diagram describing wiring in the substrate support according to the exemplary embodiment. As shown in FIG. 4, the power supply 30 includes one or more heater power supplies 33 (examples of a power supply) coupled to the first heaters 51 and the second heaters 61. The heater power supplies 33 in the plasma processing apparatus 1 include multiple heater power supplies 331 to 33M. The connection between the heater power supplies 33 and the first heaters 51 and between the heater power supplies 33 and the second heaters 61 will be described in detail later.

The ESC 1111 includes a first wire EW1, a second wire EW2, and multiple third wires EW3. As shown in FIGS. 3 and 4, the ESC 1111 includes the first wire EW1 electrically coupled to the first heaters 51. For example, the first wire EW1 is electrically coupled to one end of each first heater 51 in the first layer 50. The first wire EW1 extends from each first heater 51 to the second area 1111e. The first wire EW1 may be located in the first layer 50 or in any layer other than the first layer 50. The ESC 1111 includes the second wire EW2 electrically coupled to the second heaters 61. For example, the second wire EW2 is electrically coupled to one end of each second heater 61 in the second layer 60. The second wire EW2 extends from each second heater 61 to the second area 1111e. The second wire EW2 may be located in the second layer 60 or in any layer other than the second layer 60 (refer to FIG. 3).

The first wire EW1 and the second wire EW2 may each have a linear pattern extending horizontally in the ESC 1111. The first wire EW1 and the second wire EW2 may each have a contact via extending in a direction (e.g., the vertical direction) intersecting with the linear pattern. The first wire EW1 is electrically coupled to a contact CT1 in the second area 1111e. The second wire EW2 is electrically coupled to a contact CT2 in the second area 1111e. For example, the first wire EW1 forms the contact CT1 in the second area 1111e. The second wire EW2 forms the contact CT2 in the second area 1111e. The contacts CT1 and CT2 are exposed through the lower surface of the ESC 1111 in the second area 1111e.

The ESC 1111 also includes the multiple third wires EW3 electrically coupled to the respective first heaters 51. The third wires EW3 are electrically coupled to the respective second heaters 61. The ESC 1111 includes M third wires, or third wires EW31 to EW3M. Each third wire EW3 is electrically coupled to the other end of the corresponding first heater 51 of the multiple first heaters 51 and to the other end of the corresponding second heater 61 of the multiple second heaters 61. Each third wire EW3 extends from the other end of the corresponding first heater 51 and the other end of the corresponding second heater 61 to the second area 1111e. The third wires EW3 may be located in the first layer 50 and the second layer 60 or in any layers other than the first layer 50 and the second layer 60.

Each third wire EW3 may have a linear pattern extending horizontally in the ESC 1111. Each third wire EW3 may have a contact via extending in a direction (e.g., the vertical direction) intersecting with the linear pattern. Each third wire EW3 is electrically coupled to the corresponding contact CT3 of multiple contacts CT3 in the second area 1111e. For example, the third wires EW3 form the contacts CT3 in the second area 1111e. The contacts CT3 are exposed through the lower surface of the ESC 1111 in the second area 1111e.

In the example shown in FIG. 3, the ESC 1111 further includes a fourth wire EW4 electrically coupled to the electrostatic electrode 1111b. The ESC 1111 includes a fifth wire EW5 electrically coupled to the lower electrode 1111c. For example, the fourth wire EW4 and the fifth wire EW5 may each have a linear pattern extending horizontally in the ESC 1111. The fourth wire EW4 and the fifth wire EW5 may each have a contact via extending in a direction (e.g., the vertical direction) intersecting with the linear pattern. The fourth wire EW4 is electrically coupled to a contact CT4 in the second area 1111e. The fifth wire EW5 is electrically coupled to a contact CT5 in the second area 1111e. For example, the fourth wire EW4 forms the contact CT4 in the first area 1111d. The fifth wire EW5 forms the contact CT5 in the first area 1111d. The contacts CT4 and CT5 are exposed through the lower surface of the ESC 1111 in the first area 1111d.

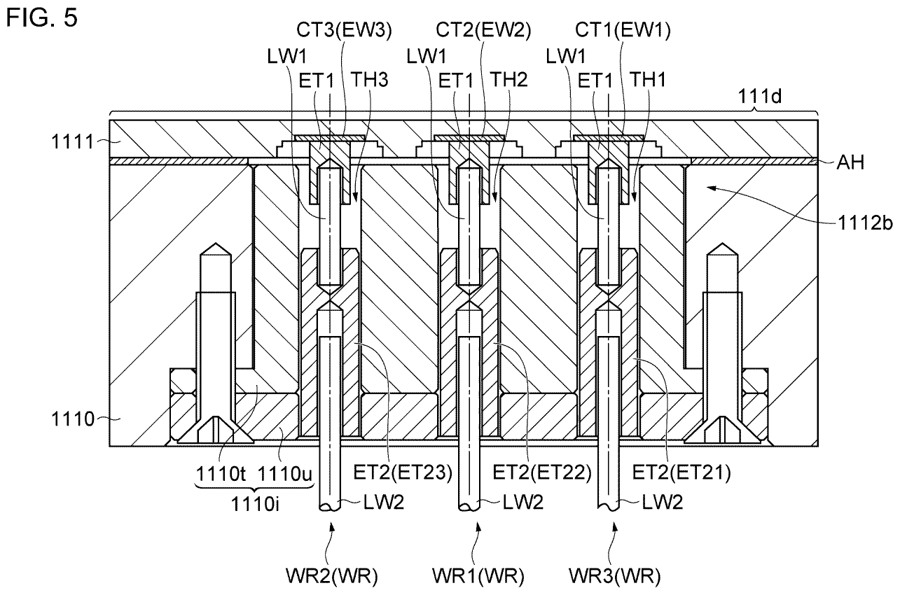

FIG. 5 is a partial cross-sectional view of terminals in the substrate support with an example structure according to the exemplary embodiment. As shown in FIG. 5, the ESC 1111 is located on the base 1110. In one embodiment, the ESC 1111 is bonded to the base 1110 with an adhesive AH. The base 1110 includes an area 1112b. The area 1112b extends below the second area 1111e in the ESC 1111. The base 1110 defines one or more through-holes TH1 and one or more through-holes TH2 both extending through the area 1112b. Each through-hole TH1 connects with the corresponding contact CT1. Each through-hole TH2 connects with the corresponding contact CT2.

The base 1110 defines one or more through-holes TH3 extending through the area 1112b. These through-holes TH3 connect with the respective contacts CT3. The numbers of through-holes TH1, TH2, and TH3 are determined based on the numbers of contacts CT1, CT2, and CT3. Although not shown in FIG. 5, multiple through-holes extend vertically in an area below the first area 1111d. These through-holes connect with the contacts CT4 and CT5. The number of through-holes in the area is determined based on the numbers of contacts CT4 and CT5.

The base 1110 further includes insulators 1110i. The insulators 1110i are insulating members formed from, for example, a resin. The insulators 1110i are received in the through-holes in the base 1110 and fastened to the ESC 1111 with fasteners such as screws. The base 1110 includes multiple insulators 1110i. Each insulator 1110i may have an upper portion 1110t and a lower portion 1110u. The upper portion 1110t and the lower portion 1110u are separable from each other and may be fastened to each other with fasteners that fasten the insulator 1110i to a main portion of the base 1110. One of the multiple insulators 1110i has, for example, at least one of the through-hole TH1, the through-hole TH2, or the through-hole TH3. In the example shown in FIG. 5, the insulator 1110i defines the through-hole TH1, the through-hole TH2, and the through-hole TH3.

A wire WR1 extends through the through-hole TH1. The wire WR1 couples the heater power supplies 33 and the contact CT1. A wire WR2 extends through the through-hole TH2. The wire WR2 couples the heater power supplies 33 and the contact CT2. Multiple wires WR3 extend through the respective through-holes TH3. The wires WR3 couple the heater power supplies 33 and the respective contacts CT3. The wire WR1, the wire WR2, and the wires WR3 have substantially the same structure. Thus, the wire WR1, the wire WR2, and the wires WR3 may be hereafter collectively referred to as the wire WR. Although not shown in FIG. 5, to generate electrostatic attraction, a wire extends through a through-hole connecting with the contact CT4 to couple the contact CT4 and a power supply for applying a voltage to the electrostatic electrode 1111b. A wire extends through a through-hole connecting with the contact CT5 to couple the contact CT5 and at least one of the first RF generator 31a, the second RF generator 31b, or the first DC generator 32a.

The wire WR includes a terminal ET1, a lead wire LW1, a terminal ET2, and a lead wire LW2. The terminal ET1 is cylindrical and has one end closed and bonded to the corresponding contact. The terminal ET1 is coupled with one end of the lead wire LW1. The lead wire LW1 is flexible, or in other words, is easily bendable under stress. The lead wire LW1 has the other end coupled to the terminal ET2. The terminal ET2 is a substantially cylindrical member including a reduced-diameter portion or a closed portion between one end and the other end. The terminal ET2 has one end coupled with the other end of the lead wire LW1, and the other end coupled with the lead wire LW2.

The terminal ET1, the lead wire LW1, and the terminal ET2 of the wire WR1 are received in the through-hole TH1. The terminal ET2 of the wire WR1, or a first terminal ET21, is coupled to the first wire EW1 through the contact CT1. The terminal ET1, the lead wire LW1, and the terminal ET2 of the wire WR2 are received in the through-hole TH2. The terminal ET2 of the wire WR2, or a second terminal ET22, is coupled to the second wire EW2 through the contact CT2. The terminal ET1, the lead wire LW1, and the terminal ET2 of each wire WR3 are received in the corresponding through-hole TH3. The terminals ET2 of the multiple wires WR3, or third terminals ET23, are coupled to the respective third wires EW3 through the contacts CT3. Although FIG. 5 shows a single through-hole TH3 and a single third terminal ET23, a single insulator 1110i may include multiple through-holes TH3 and multiple third terminals ET23.

As shown in FIG. 4, the multiple heater power supplies 33 are electrically couplable to the multiple first heaters 51 with the wire WR1 and the wires WR3. The heater power supplies 33 are electrically couplable to the multiple second heaters 61 with the wire WR2 and the wires WR3. The multiple heater power supplies 331 to 33M each include a first output terminal 34 and a second output terminal 35. The first output terminals 34 of the heater power supplies 331 to 33M are coupled to the respective wires WR3. The heater power supplies 331 to 33M are thus each electrically coupled to the corresponding third terminal ET23. The second output terminals 35 of the heater power supplies 331 to 33M are each selectively coupled to either the wire WR1 or the wire WR2. The heater power supplies 331 to 33M are thus selectively and electrically coupled to either the first terminal ET21 or the second terminal ET22. The heater power supplies 331 to 33M are electrically coupled to either the first terminal ET21 or the second terminal ET22 with a switch or through a user operation.

In the example shown in FIG. 4, the substrate support 11 further includes a switch SW that allows coupling selectively to either the first terminal ET21 or to the second terminal ET22. The switch SW is located on the base 1110. The switch SW includes a first switch terminal SW1, a second switch terminal SW2, and a third switch terminal SW3. The first switch terminal SW1 is coupled to the wire WR1. The second switch terminal SW2 is coupled to the wire WR2. The third switch terminal SW3 is coupled to a wire WR5 and the heater power supplies 33. The switch SW electrically couples the third switch terminal SW3 to either the first switch terminal SW1 or the second switch terminal SW2 under the control of the controller 2 to supply power from the heater power supplies 33.

The controller 2 determines the heaters to be used for supplying power from the heater power supplies 33 based on the target temperature at which the substrate is to be heated in the plasma processing apparatus 1. When the target temperature is within the first temperature range, the controller 2 supplies power to the multiple first heaters 51. The controller 2 controls the switch SW to electrically couple the wire WR5 and the wire WR1. The second output terminals 35 of the heater power supplies 33 are thus electrically coupled to the first terminal ET21. For example, the switch SW couples the second output terminals 35 to the first terminal ET21 to allow a current to flow between the multiple heater power supplies 33 and the multiple first heaters 51 through the wire WR1, the first wire EW1, and the multiple third wires EW3.

When the target temperature is within the second temperature range, the controller 2 supplies power to the multiple second heaters 61. The second temperature range is, for example, lower than the first temperature range. The controller 2 controls the switch SW to electrically couple the wire WR5 and the wire WR2. The second output terminals 35 of the heater power supplies 33 are thus electrically coupled to the second terminal ET22. For example, the switch SW is coupled to the second terminal ET22 to allow a current to flow between the multiple heater power supplies 33 and the multiple second heaters 61 through the wire WR2, the second wire EW2, and the multiple third wires EW3. The switch SW thus couples the heater power supplies 33 to one of the first terminal ET21 or the second terminal ET22 to selectively use the multiple first heaters 51 or the multiple second heaters 61. The multiple first heaters 51 and the multiple second heaters 61 are couplable to the same heater power supplies 33.

The switch SW selects the heaters to be used based on the temperature for heating the substrate. The ESC 1111 can thus control the temperature of the substrate over a wide temperature range. This eliminates preparation of different ESCs for different target temperatures for heating the substrate. This facilitates mass production of the ESC 1111, the substrate support 11, and the plasma processing apparatus 1. The multiple heaters are included in a single layer to reduce temperature fluctuations in the substrate, thus increasing the temperature uniformity in the plane.

Although the ESC 1111 includes two layers, or the first layer 50 and the second layer 60, in the above embodiment, the ESC 1111 may include three or more layers. Each of the three or more layers may include one or more heaters having a resistance different from the resistances of one or more heaters included in other layers of the three or more layers.

Although the exemplary embodiments have been described above, the embodiments are not restrictive, and various additions, omissions, substitutions, and changes may be made. The components in the different embodiments may be combined to form another embodiment.

Various exemplary embodiments E1 to E15 included in the disclosure are described below.

### E1

A support member for supporting a substrate, the support member comprising:
a dielectric portion having a substrate support surface;
a first layer in the dielectric portion, the first layer including at least one first heater; and
a second layer in the dielectric portion, the second layer including at least one second heater having a resistance different from a resistance of the at least one first heater.

The support member according to E1 includes two heaters having different resistances. The heater having a lower resistance is suitable for heating the substrate to a high temperature. The heater having a higher resistance is suitable for heating the substrate to a relatively low temperature. The structure according to the embodiment E1 thus allows control of the temperature of the substrate over a wide temperature range.

### E2

The support member according to E1, wherein
the dielectric portion comprises ceramic.

### E3

The support member according to E1, wherein
the dielectric portion includes a plurality of layers comprising ceramic.

### E4

The support member according to any one of E1 to E3, wherein
the support member is an electrostatic chuck.

### E5

The support member according to any one of E1 to E4, wherein
the at least one first heater in the first layer includes a plurality of first heaters,
the at least one second heater in the second layer includes a plurality of second heaters, and
the support member further comprises
   a first wire electrically coupled to the plurality of first heaters,
   a second wire electrically coupled to the plurality of second heaters, and
   a plurality of third wires respectively coupled to the plurality of first heaters and respectively coupled to the plurality of second heaters.

### E6

A substrate support, comprising:
a base; and
a support member on the base, the support member being configured to support a substrate, the support member including
   a dielectric portion having a substrate support surface,
   a first layer in the dielectric portion, the first layer including at least one first heater, and
   a second layer in the dielectric portion, the second layer including at least one second heater having a resistance different from a resistance of the at least one first heater.

### E7

The substrate support according to E6, wherein
the dielectric portion comprises ceramic.

### E8

The substrate support according to E6, wherein
the dielectric portion includes a plurality of layers comprising ceramic.

### E9

The substrate support according to any one of E6 to E8, wherein
the support member is an electrostatic chuck.

### E10

The substrate support according to any one of E6 to E9, wherein
the at least one first heater in the first layer includes a plurality of first heaters,
the at least one second heater in the second layer includes a plurality of second heaters, and
the support member includes
   a first wire electrically coupled to the plurality of first heaters,
   a second wire electrically coupled to the plurality of second heaters, and
   a plurality of third wires respectively coupled to the plurality of first heaters and respectively coupled to the plurality of second heaters.

### E11

The substrate support according to E10, further comprising:
a first terminal coupled to the first wire;
a second terminal coupled to the second wire; and
a plurality of third terminals respectively coupled to the plurality of third wires.

### E12

The substrate support according to E11, further comprising:
a switch configured to allow coupling selectively to the first terminal or to the second terminal.

### E13

A plasma processing apparatus, comprising:
a chamber; and
the substrate support according to any one of E6 to E10, the substrate support being accommodated in the chamber.

### E14

A plasma processing apparatus, comprising:
a chamber;
the substrate support according to E11, the substrate support being accommodated in the chamber; and
a plurality of power supplies, each of the plurality of power supplies including
   a first output terminal coupled to a corresponding third terminal of the plurality of third terminals, and
   a second output terminal coupled to the first terminal or to the second terminal.

### E15

The plasma processing apparatus according to E14, further comprising:
a switch configured to couple the second output terminal of each of the plurality of power supplies selectively to the first terminal or to the second terminal.

The exemplary embodiments according to the disclosure have been described by way of example, and various changes may be made without departing from the scope and spirit of the disclosure. The exemplary embodiments described above are thus not restrictive, and the true scope and spirit of the disclosure are defined by the appended claims.

### REFERENCE SIGNS LIST

1 Plasma processing apparatus
2 Controller
10 Plasma processing chamber
11 Substrate support
30 Power supply
33 Heater power supply
34 First output terminal
35 Second output terminal
50 First layer
51 First heater
60 Second layer
61 Second heater
1110 Base
1111 Electrostatic chuck (example of support member)
1111a Ceramic member (example of dielectric portion)
1111b Electrostatic electrode
ET2 Terminal
ET21 First terminal
ET22 Second terminal
ET23 Third terminal
EW1 First wire
EW2 Second wire
EW3 Third wire
W Substrate
WR, WR1, WR2, WR3, WR5 Wire
SW Switch

1. A support member for supporting a substrate, the support member comprising:
a dielectric portion having a substrate support surface;
a first layer in the dielectric portion, the first layer including at least one first heater; and
a second layer in the dielectric portion, the second layer including at least one second heater having a resistance different from a resistance of the at least one first heater.

2. The support member according to claim 1, wherein
the dielectric portion comprises ceramic.

3. The support member according to claim 1, wherein
the dielectric portion includes a plurality of layers comprising ceramic.

4. The support member according to claim 1, wherein
the support member is an electrostatic chuck.

5. The support member according to claim 1, wherein
the at least one first heater in the first layer includes a plurality of first heaters,
the at least one second heater in the second layer includes a plurality of second heaters, and
the support member further comprises:
a first wire electrically coupled to the plurality of first heaters,
a second wire electrically coupled to the plurality of second heaters, and
a plurality of third wires respectively coupled to the plurality of first heaters and respectively coupled to the plurality of second heaters.

6. A substrate support, comprising:
a base; and
a support member on the base, the support member being configured to support a substrate, the support member including:
a dielectric portion having a substrate support surface;
a first layer in the dielectric portion, the first layer including at least one first heater; and
a second layer in the dielectric portion, the second layer including at least one second heater having a resistance different from a resistance of the at least one first heater.

7. The substrate support according to claim 6, wherein
the dielectric portion comprises ceramic.

8. The substrate support according to claim 6, wherein
the dielectric portion includes a plurality of layers comprising ceramic.

9. The substrate support according to claim 6, wherein
the support member is an electrostatic chuck.

10. The substrate support according to claim 6, wherein
the at least one first heater in the first layer includes a plurality of first heaters,
the at least one second heater in the second layer includes a plurality of second heaters, and
the support member includes:
a first wire electrically coupled to the plurality of first heaters;
a second wire electrically coupled to the plurality of second heaters; and
a plurality of third wires respectively coupled to the plurality of first heaters and the plurality of third wires respectively coupled to the plurality of second heaters.

11. The substrate support according to claim 10, further comprising:
a first terminal coupled to the first wire;
a second terminal coupled to the second wire; and
a plurality of third terminals respectively coupled to the plurality of third wires.

12. The substrate support according to claim 11, further comprising:
a switch configured to allow coupling selectively to the first terminal or to the second terminal.

13. A plasma processing apparatus, comprising:
a chamber; and
the substrate support according to claim 6, the substrate support being accommodated in the chamber.

14. A plasma processing apparatus, comprising:
a chamber;
the substrate support according to claim 11, the substrate support being accommodated in the chamber; and
a plurality of power supplies, each of the plurality of power supplies including:
a first output terminal coupled to a corresponding third terminal of the plurality of third terminals, and
a second output terminal coupled to the first terminal or to the second terminal.

15. The plasma processing apparatus according to claim 14, further comprising:
a switch configured to couple the second output terminal of each of the plurality of power supplies selectively to the first terminal or to the second terminal.

16. The support member according to claim 5, wherein the plurality of first heaters and the plurality of second heaters are arranged in respective horizontal planes parallel to the substrate support surface and distributed to heat the substrate uniformly.

17. The substrate support according to claim 12, wherein the switch is configured to couple the second output terminals of the heater power supplies exclusively to either the first terminal or the second terminal to prevent simultaneous operation of the plurality of first heaters and the plurality of second heaters.

18. The plasma processing apparatus according to claim 15, further comprising a controller configured to control the switch to select the plurality of first heaters when a target temperature is within a first temperature range and to select the plurality of second heaters when the target temperature is within a second temperature range lower than the first temperature range.

19. The substrate support according to claim 11, wherein the base includes a plurality of insulators received in through-holes connecting to the first terminal, the second terminal, and the plurality of third terminals, each insulator having an upper portion and a lower portion fastened to the base.

20. The support member according to claim 5, wherein each of the plurality of first heaters has a lower resistance than each of the plurality of second heaters, and
the plurality of first heaters being configured to heat the substrate at higher temperatures than the plurality of second heaters.
